(19) United States
(12) Patent Application Publication
(10) Pub. No.: US 2025/0376767 A1
(43) Pub. Date: Dec. 11, 2025

(54) ADJUSTMENT PROCESSING APPARATUS, FILM FORMING PROCESSING SYSTEM, ADJUSTMENT PROCESSING METHOD AND STORAGE MEDIUM

(71) Applicant: Tokyo Electron Limited, Tokyo (JP)

(72) Inventors: Shota YAMAZAKI, Tokyo (JP); Atsushi SHIGENOBU, Yamanashi (JP)

(21) Appl. No.: 19/228,358

(22) Filed: Jun. 4, 2025

(30) Foreign Application Priority Data
Jun. 10, 2024 (JP) 2024-093664

(51) Int. Cl. C23C 16/52

(52) U.S. Cl. CPC C23C 16/52

(57) ABSTRACT

An adjustment processing apparatus includes: a film thickness measurement result acquisition unit that acquires a film thickness measurement result of a substrate including a film formed thereon by a film forming processing apparatus; a formulation unit that formulates the film thickness measurement result using an orthogonal polynomial; and an adjustment unit that adjusts a transfer position of the substrate and a process condition of the film forming processing apparatus based on a weight of each component of the orthogonal polynomial calculated during formulation.

### CROSS-REFERENCE TO RELATED APPLICATIONS

This application is based on and claims priority from Japanese Patent Application No. 2024-093664, filed on Jun. 10, 2024, with the Japan Patent Office, the disclosure of which is incorporated herein in its entirety by reference.

### TECHNICAL FIELD

The present disclosure relates to an adjustment processing apparatus, a film forming processing system, an adjustment processing method, and a storage medium.

### BACKGROUND

In a film forming process for forming a film on a substrate, a work for adjusting a transfer position of the substrate and a work for adjusting a process condition are performed to implement an appropriate film thickness distribution.

The work for adjusting the transfer position of the substrate refers to a work for adjusting the transfer position of the substrate such that a deviation between the center position of the film thickness distribution and the center position of the substrate is eliminated, for example, when a film is formed on the substrate and the film thickness distribution is concentrically formed. In addition, the work for adjusting a process condition refers to a work for adjusting the process condition such that, for example, the variation in film thicknesses at in-plane locations on the substrate is eliminated and the film thicknesses become uniform.

Meanwhile, eliminating the deviation between the center positions and making the film thicknesses at in-plane locations uniform have conventionally been recognized as independent adjustment operations. Thus, these adjustment operations have been separately performed as two stages. For this reason, a lot of time was required for the adjustment operations in the film forming process. See, for example, Japanese Patent Laid-Open Publication No. 2024-007897.

### SUMMARY

According to an aspect of the present disclosure, an adjustment processing apparatus has, for example, the following configuration. That is, the adjustment processing apparatus includes: a film thickness measurement result acquisition unit that acquires a film thickness measurement result of a substrate including a film formed thereon by a film forming processing apparatus; a formulation unit that formulates the film thickness measurement result using an orthogonal polynomial; and an adjustment unit that adjusts a transfer position of the substrate and a process condition of the film forming processing apparatus based on a weight of each component of the orthogonal polynomial calculated during formulation.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a view illustrating an example of a system configuration of a film forming processing system.

FIG. 2 is a view illustrating a schematic configuration example of a film forming processing apparatus.

FIG. 3 is a view illustrating a schematic configuration example of a transfer device and a schematic configuration example of the inside of a reaction vessel in the film forming processing apparatus.

FIG. 4A is a view illustrating a transfer example of substrates transferred into the reaction vessel by the transfer device.

FIG. 4B is a view for explaining an adjustment method of a transfer position.

FIG. 5 is a view illustrating an example of measurement points at which film thicknesses are measured by a film thickness measuring device.

FIG. 6 is a view illustrating an example of a hardware configuration of an adjustment processing apparatus.

FIG. 7 is a view illustrating an example of a functional configuration of the adjustment processing apparatus.

FIGS. 8A and 8B are views illustrating an example of the Zernike polynomial.

FIGS. 9A to 9C are views illustrating an example of a Fringe notation method for the Zernike polynomial.

FIG. 10 is a view illustrating a specific example of processing by a formulation unit.

FIGS. 11A and 11B are views illustrating an example of a film thickness measurement result before adjustment processing, and the weight of each component in the Zernike polynomial.

FIG. 12 is a view illustrating a specific example of processing by a transfer position adjustment unit.

FIG. 13 is a view illustrating a specific example of processing by a process condition adjustment unit.

FIG. 14 is a flow chart illustrating the flow of adjustment processing by a film forming processing system of a Comparative Example.

FIG. 15 is a flow chart illustrating the flow of adjustment processing by the film forming processing system.

FIGS. 16A and 16B are views illustrating an example of the film formation result after adjustment processing by the film forming processing system, and the weight of each component in the Zernike polynomial.

### DETAILED DESCRIPTION

In the following detailed description, reference is made to the accompanying drawings, which form a part hereof. The illustrative embodiments described in the detailed description, drawings, and claims are not meant to be limiting. Other embodiments may be utilized, and other changes may be made without departing from the spirit or scope of the subject matter presented here.

Hereinafter, each embodiment will be described with reference to the accompanying drawings. In this specification and drawings, components having substantially the same functional configurations are denoted by the same reference numerals, and redundant descriptions will be omitted.

### First Embodiment

### <System Configuration of Film Forming Processing System>

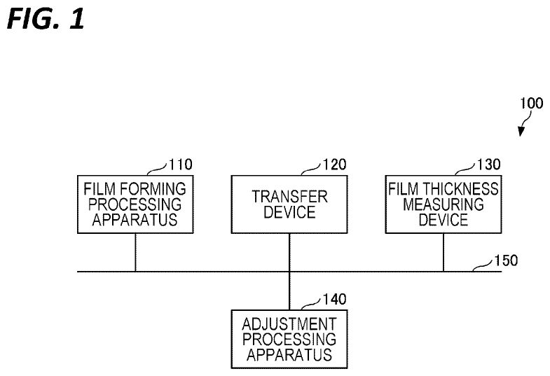

First, a system configuration of a film forming processing system according to a first embodiment will be described. FIG. 1 is a view illustrating an example of a system configuration of a film forming processing system. A film forming processing system 100 is a system related to a film forming process for forming a film on a substrate, and includes a film forming processing apparatus 110, a transfer device 120, a film thickness measuring device 130, and an adjustment processing apparatus 140 as illustrated in FIG. 1. In the film forming processing system 100, the film forming processing apparatus 110, the transfer device 120, the film thickness measuring device 130, and the adjustment processing apparatus 140 are connected via a network 150 in such a manner that communication is possible.

In the first embodiment, among various functions executed by each device of the film forming processing system 100 related to a film forming process, descriptions will be made on functions related to adjustment processing for implementing a film thickness distribution that satisfies predetermined requirements. The adjustment processing mentioned herein includes processing for adjusting a transfer position of the substrate, and processing for adjusting a process condition.

The film forming processing apparatus 110 is an apparatus that forms a film on the substrate based on a predetermined process condition. The process condition used for forming a film on the substrate is adjusted by the adjustment processing apparatus 140, and is set in the film forming processing apparatus 110.

The transfer device 120 transfers a substrate on which a film has not yet been formed, to a wafer port (details will be described below) in a reaction vessel included in the film forming processing apparatus 110. When the transfer device 120 transfers the substrate on which a film has not yet been formed, the adjustment amount for adjusting the transfer position within the wafer port is calculated by the adjustment processing apparatus 140, and is set in the transfer device 120.

The film thickness measuring device 130 measures the film thickness at each location on the substrate on which a film has been formed by the film forming processing apparatus 110. The film thickness measurement result measured by the film thickness measuring device 130 is sent to the adjustment processing apparatus 140.

The adjustment processing apparatus 140 acquires the film thickness measurement result indicating the film thickness at each location on the substrate on which a film has been formed by the film forming processing apparatus 110, from the film thickness measuring device 130. The adjustment processing apparatus 140 formulates the acquired film thickness measurement result using an orthogonal polynomial (e.g., Zernike polynomial) to calculate the weight of each component of the orthogonal polynomial. Based on the calculated weight of each component, the adjustment processing apparatus 140
calculates the adjustment amount of the transfer position of the substrate to eliminate the deviation between the center position of the film thickness distribution and the center position of the substrate when the film thickness distribution is concentrically formed for film formation on the substrate, and.
adjusts a process condition to eliminate the variation in the film thicknesses at locations on the substrate and make the film thicknesses uniform.

The adjustment processing apparatus 140 sets the adjustment amount of the transfer position of the substrate, to the transfer device 120, and sets the adjusted process condition, to the film forming processing apparatus 110.

In this manner, in the configuration of the film forming processing apparatus 110, from the film thickness measurement result acquired by one film formation,
the weight of each component of the orthogonal polynomial is calculated as an index value including both
information for calculating the adjustment amount of the transfer position of the substrate, and
information for adjusting a process condition.

This configuration for index value calculation is made in consideration of the fact that eliminating the deviation between the center positions and eliminating the variation in the film thicknesses at locations and making the film thicknesses uniform are mutually influential adjustment operations.

Here, eliminating the deviation between the center positions and eliminating the variation in the film thicknesses at locations and making the film thicknesses uniform have conventionally been recognized as independent adjustment operations. Thus, the work of adjusting the transfer position of the substrate and the work of adjusting the process condition were separately performed as two stages, and a lot of time was required for the adjustment operations in the film forming process.

Meanwhile, by using the adjustment processing apparatus 140 configured to calculate the index value, the adjustment operations do not need to be separately performed as two stages, and it is possible to shorten the time required for the adjustment operations in the film forming process.

### <Details of Each Device Included in Film Forming Processing System>

Thereafter, descriptions will be made on details of each device included in the film forming processing system 100 (here, the film forming processing apparatus 110, the transfer device 120, and the film thickness measuring device 130).

### (1) Schematic Configuration Example of Film Forming Processing Apparatus

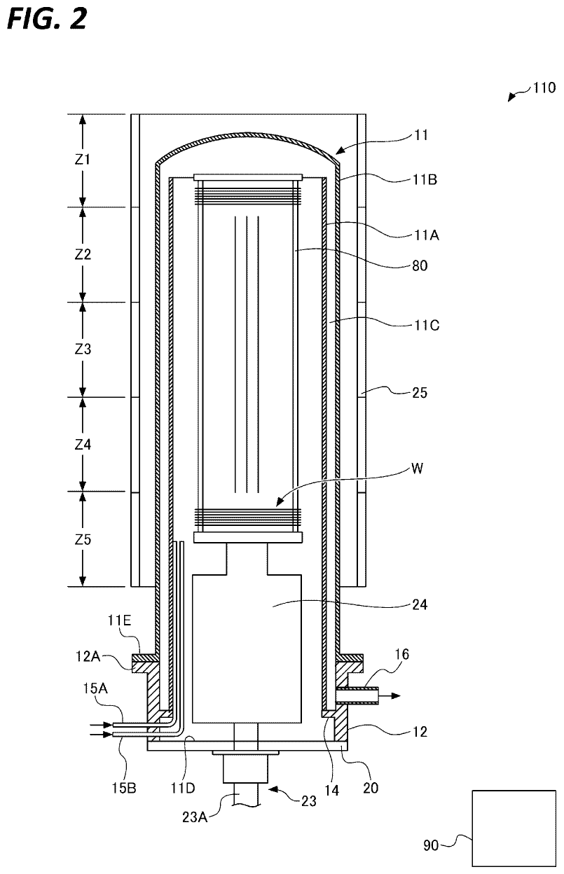

First, a schematic configuration example of the film forming processing apparatus 110 will be described. FIG. 2 is a view illustrating the schematic configuration example of the film forming processing apparatus.

The film forming processing apparatus 110 includes a reaction vessel 11 having a double-tube structure of a straight inner tube 11A and an outer tube 11B. The straight inner tube 11A is disposed in the height direction (e.g. the vertical direction in FIG. 2). The upper end of the straight inner tube 11A is open. The outer tube 11B is disposed concentrically with the inner tube 11A at a predetermined gap such that a cylindrical space 11C is formed around the inner tube 11A. The upper end of the outer tube 11B is open. The straight inner tube 11A and the outer tube 11B are made of a material excellent in heat resistance and corrosion resistance, for example, high-purity quartz glass.

A cylindrical heater 25 is provided outside the reaction vessel 11 while surrounding the periphery of the reaction vessel 11. The cylindrical heater 25 functions as a heating unit that heats substrates W accommodated in the reaction vessel 11. The cylindrical heater 25 is provided with a cylindrical heat insulating material (not illustrated). In the cylindrical heat insulating material, a linear resistance heating element is disposed spirally or meanderingly on the inner surface. The resistance heating element is connected to a control device 90, and the control device 90 controls the magnitude of power to be supplied so that substrates W reach a preset temperature. The control device 90 is configured to control not only the resistance heating element, but also the operation of the entire film forming processing apparatus 110.

For example, in a state where the inside of the reaction vessel 11 is divided into a plurality of heating zones in the height direction (e.g., five heating zones Z1 to Z5 in the example of FIG. 2), the cylindrical heater 25 is configured to independently control the temperature for each of the heating zones Z1 to Z5.

The reaction vessel 11 has a lower space. The lower space of the reaction vessel 11 is a loading area where substrates W as processing targets are transferred to/from a wafer port 80 as a processing target holder to be described below, by the transfer device 120 (not illustrated in FIG. 2).

A short cylindrical manifold 12 is provided at the lower end of the outer tube 11B in the reaction vessel 11. The manifold 12 has a flange portion 12A at the upper end thereof. A lower end flange portion 11E provided at the lower end of the outer tube 11B is joined to the flange portion 12A via, for example, a sealing unit (not illustrated) such as an O ring. This maintains the outer tube 11B of the reaction vessel 11 in an airtight fixed state.

The inner tube 11A in the reaction vessel 11 extends downward from the lower end surface of the outer tube 11B and is inserted into the manifold 12. An annular inner tube support 14 is provided on the inner surface of the manifold 12, and supports the inner tube 11A inserted into the manifold 12.

In the vertical cross section of the reaction vessel 11, gas supply pipes 15A and 15B are provided on one side wall of the manifold 12. The gas supply pipe 15A introduces a processing gas into the reaction vessel 11. The gas supply pipe 15B introduces an inert gas into the reaction vessel 11. The gas supply pipes 15A and 15B airtightly pass through the side wall of the manifold 12 and are provided in the inner tube 11A in the vertical direction. Gas supply sources (not illustrated) are connected to the gas supply pipes 15A and 15B, respectively.

In the vertical cross section of the reaction vessel 11, an exhaust pipe 16 is provided on the other side surface of the manifold 12. The exhaust pipe 16 is provided in communication with the cylindrical space 11C between the inner tube 11A and the outer tube 11B. An exhaust mechanism (not illustrated) having, for example, a vacuum pump and a pressure control mechanism is connected to the exhaust pipe 16, whereby the pressure inside the reaction vessel 11 is controlled to a predetermined pressure.

Below the reaction vessel 11, a lifting mechanism (not illustrated) is provided. The lifting mechanism is driven in the vertical direction and loads/unloads the wafer port 80 into/from the reaction vessel 11. The lifting mechanism includes a disk-shaped lid 20 that opens/closes a lower end opening 11D of the reaction vessel 11. A rotary driving unit 23 is provided on the lower portion of the lid 20. The rotary driving unit 23 airtightly passes through the lid 20. A rotary driving shaft 23A of the rotary driving unit 23 is connected to the lower surface of a heat insulating cylinder (heat insulating body) 24.

### (2) Schematic Configuration Example of Transfer Device and Schematic Configuration Example of Inside of Reaction Vessel

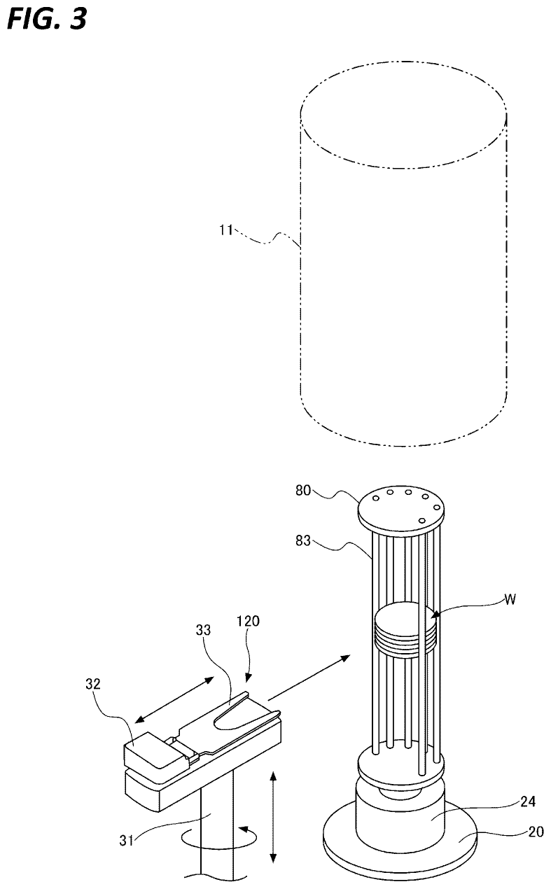

Next, descriptions will be made on a schematic configuration of the transfer device 120 that transfers substrates W to the wafer port 80 in the loading area, and a schematic configuration of the inside of the reaction vessel 11 where substrates W are transferred to the wafer port 80 by the transfer device 120. FIG. 3 is a view illustrating a schematic configuration example of the transfer device and a schematic configuration example of the inside of the reaction vessel.

The wafer port 80 is made of, for example, high-purity quartz glass. As illustrated in FIG. 3, a plurality of (e.g., about 100 to 150) disc-shaped substrates W is held in the horizontal direction in the wafer port 80. In the wafer port 80, processing target holding portions such as, for example, processing target retaining grooves, are formed on struts 83 such that the substrates W are vertically held in multiple stages at a predetermined interval (pitch) within a range of, for example, 4 to 20 mm. In a state where the lid 20 is at the lowest position in the loading area, the substrates W are transferred by the transfer device 120.

The transfer device 120 includes an elongated rectangular transfer head 32. The transfer head 32 is vertically moved up and down and is rotatably provided around a vertically extending rotary shaft 31. The transfer head 32 is provided with, for example, 1 to 5 thin-plate fork-shaped support arms 33 such that the support arms 33 can advance and retreat in the longitudinal direction of the transfer head 32. In the transfer device 120, the vertical operation and the rotational operation of the transfer head 32, and the forward/backward operation of the support arms 33 are controlled by a control device (not illustrated).

Accordingly, the substrates W are taken out of a storage container which has been transported by an appropriate conveyance unit (not illustrated). Then, in the loading area, in a state where the lid 20 is at the lowest position, the substrates W are sequentially transferred to the wafer port 80 waiting on the lid 20.

In each of the processing target holding portions in the wafer port 80, the transfer position to which the substrate W is transferred is, for example, a position that coincides with the rotation center position of the wafer port 80. The transfer position to which the substrate W is transferred is adjusted in advance by setting the adjustment amount calculated by the adjustment processing apparatus 140 to the transfer device 120. The wafer port 80 is rotationally driven by the rotary driving unit 23. For example, simulated substrates (dummy wafers) are placed on the uppermost and lowermost processing target holding portions in the wafer port 80.

As the lid 20 is driven upward by the lifting mechanism, the wafer port 80 is carried into the reaction vessel 11 through the lower end opening 11D, and the lower end opening 11D of the reaction vessel 11 is placed in an airtightly closed state by the lid 20. Next, an exhaust unit is operated to decompress the inside of the reaction vessel 11 to a predetermined pressure, and the cylindrical heater 25 is operated so that each of the heating zones Z1 to Z5 in the reaction vessel 11 is heated to a target temperature at which the substrates W are to be processed.

When the heating zones Z1 to Z5 are heated, a processing gas is appropriately introduced into the reaction vessel 11 through the gas supply pipe 15A, and films are formed on the substrates W. As described above, the process condition (e.g., the target temperature, the type of processing gas, the gas flow rate, or the gas introduction time) used in the film formation of the substrates W is adjusted by the adjustment processing apparatus 140, and is set in advance in the film forming processing apparatus 110.

### (3) Transfer Example of Substrates in Reaction Vessel

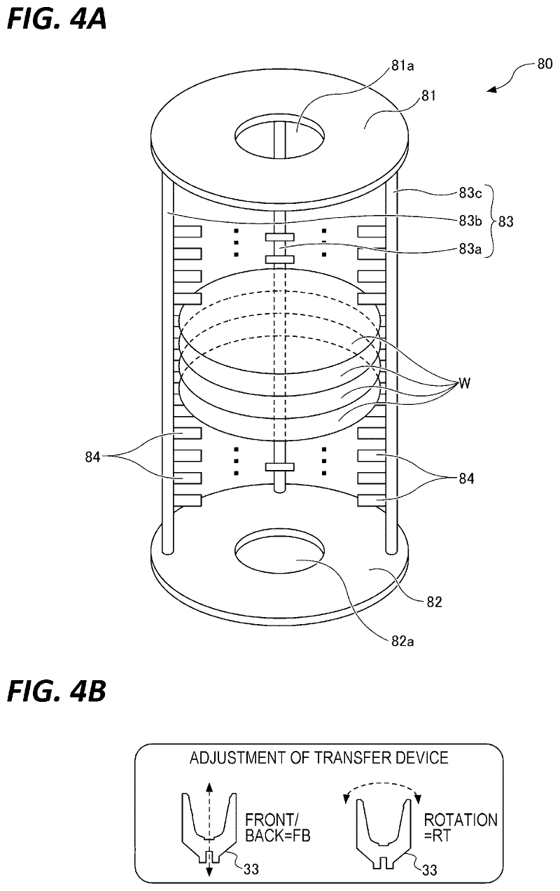

Next, descriptions will be made on a transfer example of substrates W in the reaction vessel 11. FIG. 4A is a view illustrating a transfer example of substrates in the reaction vessel. As illustrated in FIG. 4A, the wafer port 80 includes a top plate 81 and a bottom plate 82, and includes the struts 83 between the top plate 81 and the bottom plate 82. FIG. 4A illustrates an example in which three struts 83 are provided. The number of the struts 83 may be set depending on applications as long as it is three or more, and the number of the struts 83 may also be set to, for example, four.

Each strut 83 has supporting portions 84 vertically formed at predetermined intervals. The spacing between the supporting portions 84 may be appropriately set according to applications, but the spacing between the supporting portions 84 may be set such that, for example, 50 to 150 substrates W are arranged in one wafer port 80 as described above.

There is no limitation in the shape of the supporting portion 84 as long as the supporting portion 84 can support the substrate W. For example, the supporting portion 84 may be formed in a rectangular shape having a horizontal surface extending toward the center. The individual supporting portions 84, which support the same substrate W, are configured to support the substrate W in the horizontal state. Specifically, the individual supporting portions 84, which support the same substrate W, are set at the same height. Also, in a case where there are three struts 83, when viewed from the front side where the substrates W are mounted, one strut 83a is arranged at the central rear side, and the other two struts 83b and 83c are arranged symmetrically with respect to the strut 83a.

The top plate 81 and the bottom plate 82 may be formed in annular shapes having an opening 81a and an opening 82a, respectively, in the central regions thereof. In addition to the struts 83, if necessary, the wafer port 80 may include a reinforcing pillar. The reinforcing pillar is a support pillar that is provided for reinforcement in order to increase the strength of the wafer port 80, and does not have the supporting portions 84 that support the substrates W.

In a configuration example, one reinforcing pillar may be provided between the central rear strut 83a and the left strut 83b, and one reinforcing pillar may be provided between the central rear strut 83a and the right strut 83c. The wafer port 80 may be made of various materials depending on the applications, including quartz that is the same material as that for the wafer port support base.

Here, as illustrated in FIG. 2, since the gas supply pipe 15A is disposed outside the substrates W, the distance from the gas supply pipe 15A varies depending on in-plane positions of the substrate W. Thus, when a film is formed by a processing gas, the film thickness may vary at in-plane positions of the substrate W.

### (4) Adjustment Method of Transfer Position

Next, descriptions will be made on an adjustment method of adjusting the transfer position of the substrate W transferred to the wafer port 80. FIG. 4B is a view for explaining an adjustment method of the transfer device. The transfer device 120 moves the support arm 33 in the front-rear direction and the rotational direction based on the notified transfer position of the substrate W, and transfers the substrate W onto the supporting portions 84 of the wafer port 80.

For example, in a case where a plurality of substrates W is transferred and film formation is performed for one batch, the transfer device 120 is notified that the center positions of the substrates W transferred to vertical locations, respectively, are transfer positions. Specifically, the transfer device 120 is notified of movement amounts of the support arm 33 in the front-rear direction and the rotational direction from the base position.

This allows the support arm 33 to be moved in the front-rear direction and the rotational direction from the base position of the wafer port 80 so as to transfer the substrates W onto the supporting portions 84. As described above, the transfer position of the substrate W is adjusted based on the adjustment amount that is calculated by the adjustment processing apparatus 140 and is set in the transfer device 120 in advance.

### (5) Measurement Point of Film Thickness Measuring Device

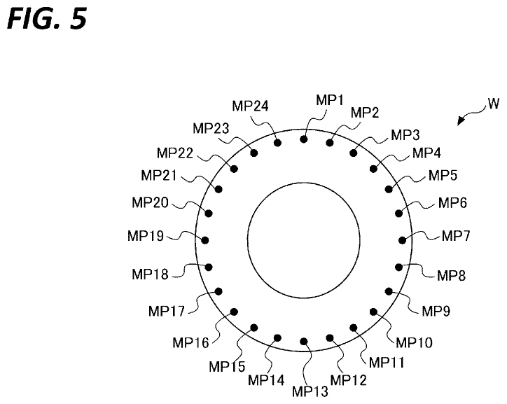

Thereafter, descriptions will be made on measurement points when the film thickness measuring device 130 measures the film thickness at each position on the substrate W. FIG. 5 is a view illustrating an example of measurement points at which film thicknesses are measured by the film thickness measuring device. As illustrated in FIG. 5, the film thickness measuring device 130 measures film thicknesses at in-plane measurement points MP1 to MP24 on the substrate W. The film thickness measuring device 130 transmits the “film thickness measurement result” which includes the coordinates of the in-plane measurement points MP1 to MP24 on the substrate W and the film thicknesses of the in-plane measurement points MP1 to MP24 on the substrate W, to the adjustment processing apparatus 140. The number of measurement points illustrated in FIG. 5 and the locations of the measurement points are examples, and are not limited thereto.

### <Hardware Configuration of Adjustment Processing Apparatus>

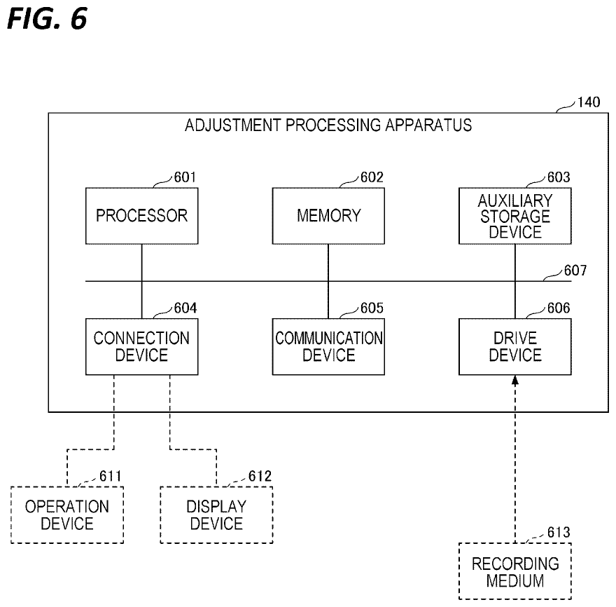

Thereafter, the hardware configuration of the adjustment processing apparatus 140 will be described. FIG. 6 is a view illustrating an example of the hardware configuration of the adjustment processing apparatus. As illustrated in FIG. 6, the adjustment processing apparatus 140 includes a processor 601, a memory 602, an auxiliary storage device 603, a connection device 604, a communication device 605, and a drive device 606. Hardware components included in the adjustment processing apparatus 140 are connected to each other via a bus 607.

The processor 601 has various arithmetic devices such as a central processing unit (CPU) and a graphics processing unit (GPU). The processor 601 reads and executes various programs (for example, an adjustment processing program, etc.) on the memory 602.

The memory 602 has a main storage device such as a read only memory (ROM) and a random access memory (RAM). The processor 601 and the memory 602 form a so-called computer, and the processor 601 executes various programs read on the memory 602 so that the computer realizes various functions.

The auxiliary storage device 603 stores various programs or various information used when the various programs are executed by the processor 601.

The connection device 604 connects external devices (e.g., an operation device 611 and a display device 612) to the adjustment processing apparatus 140.

The communication device 605 transmits and receives various information to/from the film forming processing apparatus 110, the transfer device 120, the film thickness measuring device 130, and the adjustment processing apparatus 140.

The drive device 606 is a device for setting a recording medium 613. The recording medium 613 mentioned herein includes a medium, such as a CD-ROM, a flexible disk, and a magneto-optical disc, in which information is optically, electrically, or magnetically recorded. Also, the recording medium 613 may include, for example, a semiconductor memory such as a ROM and a flash memory, in which information is electrically recorded.

Various programs to be installed in the auxiliary storage device 603 are installed, for example, by setting the distributed recording medium 613 in the drive device 606, and reading the various programs recorded in the recording medium 613 by the drive device 606. Alternatively, various programs to be installed in the auxiliary storage device 603 may be installed by being downloaded from a network (not illustrated) via the communication device 605.

### <Functional Configuration of Adjustment Processing Apparatus>

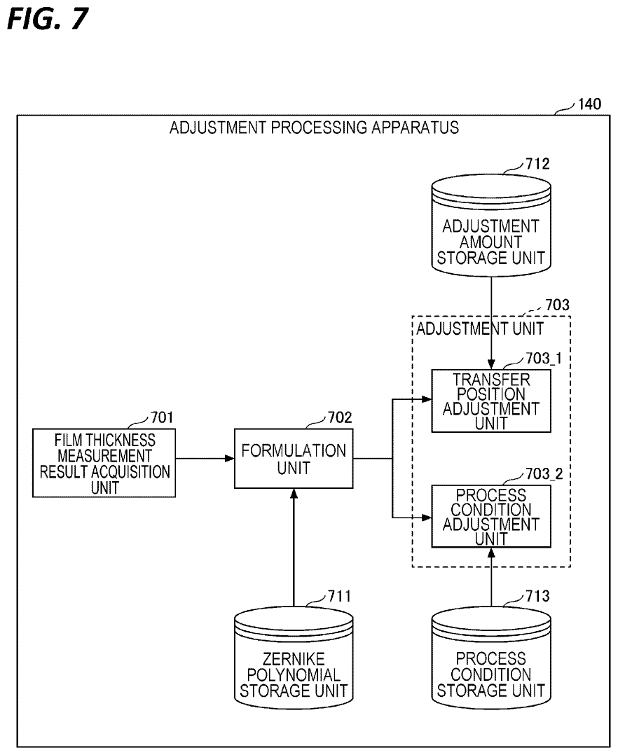

Next, the functional configuration of the adjustment processing apparatus 140 will be described. FIG. 7 is a view illustrating an example of the functional configuration of the adjustment processing apparatus. As described above, an adjustment processing program is installed in the adjustment processing apparatus 140. By executing the program in the adjustment processing apparatus 140, the adjustment processing apparatus 140 functions as a film thickness measurement result acquisition unit 701, a formulation unit 702, and an adjustment unit 703.

The film thickness measurement result acquisition unit 701 acquires a film thickness measurement result, which is measured by the film thickness measuring device 130 and includes the film thickness at each location on the substrate W, from the film thickness measuring device 130. The film thickness measurement result acquisition unit 701 notifies the formulation unit 702 of the acquired film thickness measurement result.

The formulation unit 702 formulates the film thickness measurement result notified by the film thickness measurement result acquisition unit 701 using an orthogonal polynomial. As illustrated in FIG. 7, the adjustment processing apparatus 140 according to the present embodiment includes a Zernike polynomial storage unit 711, and the formulation unit 702 reads a Zernike polynomial from the Zernike polynomial storage unit 711, as an orthogonal polynomial, and performs formulation.

Specifically, the formulation unit 702 calculates the weight of each component such that the sum of squared errors between output values obtained by inputting coordinates of locations included in the film thickness measurement result, into the components of the Zernike polynomial, and the film thicknesses corresponding to the coordinates of locations included in the film thickness measurement result is minimized. The formulation unit 702 notifies the adjustment unit 703 of the calculated weight of each component.

The adjustment unit 703 includes a transfer position adjustment unit 703_1, and a process condition adjustment unit 703_2. The transfer position adjustment unit 703_1 extracts a first component from weights of components of the Zernike polynomial notified by the formulation unit 702, and calculates the adjustment amount in adjusting the transfer position of the substrate W, by using the extracted first component.

The first component is a component related to a deviation amount between the center position of the film thickness distribution and the center position of the substrate W, among the components of the Zernike polynomial, when the film thickness distribution is concentrically formed. The transfer position adjustment unit 703_1 extracts the weights of the components, thereby specifying the deviation amount. Assuming that the relationship between the weight of the first component and the deviation amount is defined by, for example, a predetermined function, the transfer position adjustment unit 703_1 specifies the deviation amount by using the predetermined function. Based on the specified deviation amount, the transfer position adjustment unit 703_1 calculates the adjustment amount for adjusting the transfer position of the substrate W.

Here, it is assumed that the transfer position adjustment unit 703_1 specifies the deviation amount, and calculates the adjustment amount for adjusting the transfer position of the substrate W based on the specified deviation amount. However, the method for calculating the adjustment amount for adjusting the transfer position of the substrate W is not limited to this, and in another configuration, for example, the adjustment amount for adjusting the transfer position of the substrate W may be directly calculated by using the extracted weight of the first component.

In this case, for example, it is assumed that in an adjustment amount storage unit 712, information is stored in advance, which indicates the correspondence between the weight pattern of the first component, and the adjustment amount pattern for adjusting the transfer position of the substrate W. Then, the transfer position adjustment unit 703_1 searches for a weight pattern similar to the weight pattern of the first component notified by the formulation unit 702, and reads an adjustment amount pattern associated with the detected weight pattern, from the adjustment amount storage unit 712, so as to calculate the adjustment amount.

The process condition adjustment unit 703_2 extracts a second component from weights of components of the Zernike polynomial notified by the formulation unit 702, and adjusts a process condition by using the extracted second component.

The second component is a component related to a process condition for uniformizing film thicknesses at locations, among the components of the Zernike polynomial. The process condition adjustment unit 703_2 extracts the weights of the components, thereby adjusting the process condition. The second component may be different from the first component, or some or all thereof may overlap with the first component.

Specifically, the process condition adjustment unit 703_2 refers to a process condition storage unit 713 in which the weight pattern of the second component and the process condition pattern for eliminating the variation in film thicknesses at locations and making the film thicknesses uniform are stored in association with each other in advance. The process condition adjustment unit 703_2 searches for a weight pattern similar to the weight pattern of the second component notified by the formulation unit 702. Then, the process condition adjustment unit 703_2 reads a process condition pattern associated with the detected weight pattern from the process condition storage unit 713 to adjust the process condition.

The adjustment amount calculated by the transfer position adjustment unit 703_1 is sent to the transfer device 120, and the process condition adjusted by the process condition adjustment unit 703_2 are sent to the film forming processing apparatus 110. Accordingly, the transfer device 120 adjusts the transfer position based on the notified adjustment amount, and the film forming processing apparatus 110 forms a film on the substrate W based on the notified process condition.

### <Description of Zernike Polynomial>

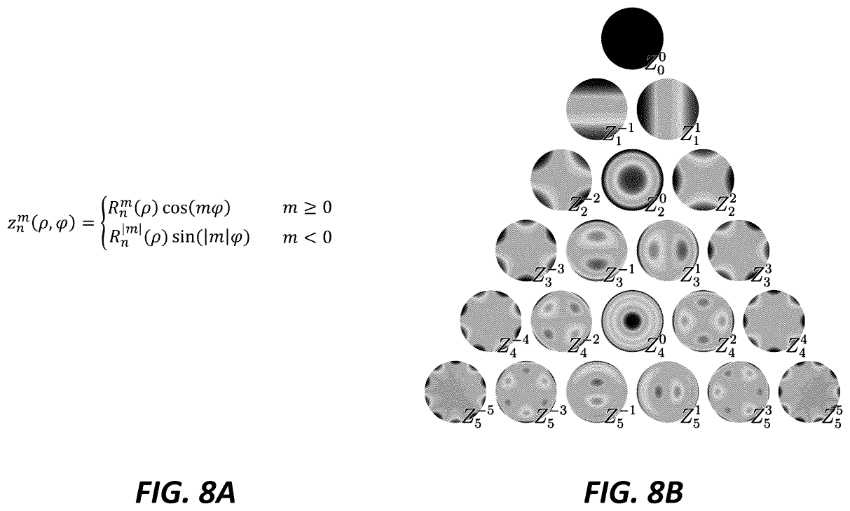

Next, the Zernike polynomial, which is an example of an orthogonal polynomial used when the formulation unit 702 formulates the film thickness measurement result, will be described. FIGS. 8A and 8B are views illustrating an example of the Zernike polynomial. The Zernike polynomial is an orthogonal polynomial defined on a unit circle, and is expressed by the following formula as illustrated in FIG. 8A.

$${z}_{n}^{m} ( ρ , φ ) = \{ \begin{matrix}{R}_{n}^{m} ( ρ ) cos ( m φ ) & m \geq 0 \\ {R}_{n}^{\vert m \vert} ( ρ ) sin ( \vert m \vert φ ) & m < 0\end{matrix}$$

In Formula (1), n is a non-negative integer, and m is an integer of n≥|m|. Also, in FIG. 8A, ρ represents a radial coordinate (0≤ρ≤1), and φ represents an angle of deviation. The output of the Zernike polynomial

$${z}_{n}^{m} ( ρ , φ )$$

takes a value in the range of −1 to +1.

Also, each component of the Zernike polynomial

$${R}_{n}^{m} ( ρ )$$

$$or$$

$${R}_{n}^{\vert m \vert} ( ρ )$$

is present corresponding to the number of combinations of m and n. FIG. 8B illustrates the value of each component (the component corresponding to the combination of m and n) of the Zernike polynomial, at each position within a unit circle.

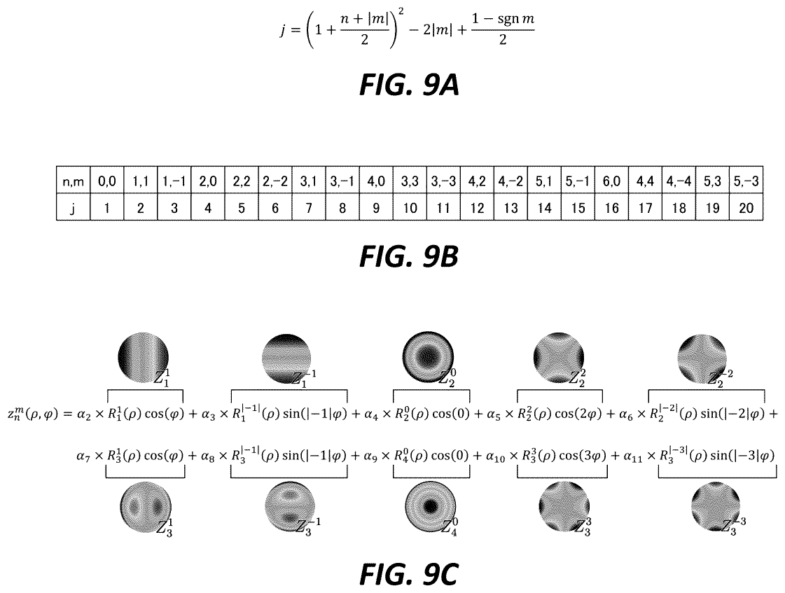

Various notation methods are defined for the Zernike polynomial. FIGS. 9A to 9C are views illustrating an example of a Fringe notation method for the Zernike polynomial. Among these, FIG. 9A illustrates a specific example of a Fringe notation method, and the combination of “n” and “m” in FIG. 9B corresponds to the combination of “n” and “m” in FIG. 8B. In FIG. 9B, “j” is a number that identifies each component.

In FIG. 9C, as an example of the Fringe notation method, by using components j of 2 to 11, the output values of the Zernike polynomial are expressed. For reference, the value of each component, at each position within the unit circle, is illustrated in association with each component. In the example of FIG. 9C, the weights of components j of 2 to 11 are set as α₂ to α₁₁.

### <Specific Example of Processing by Formulation Unit>

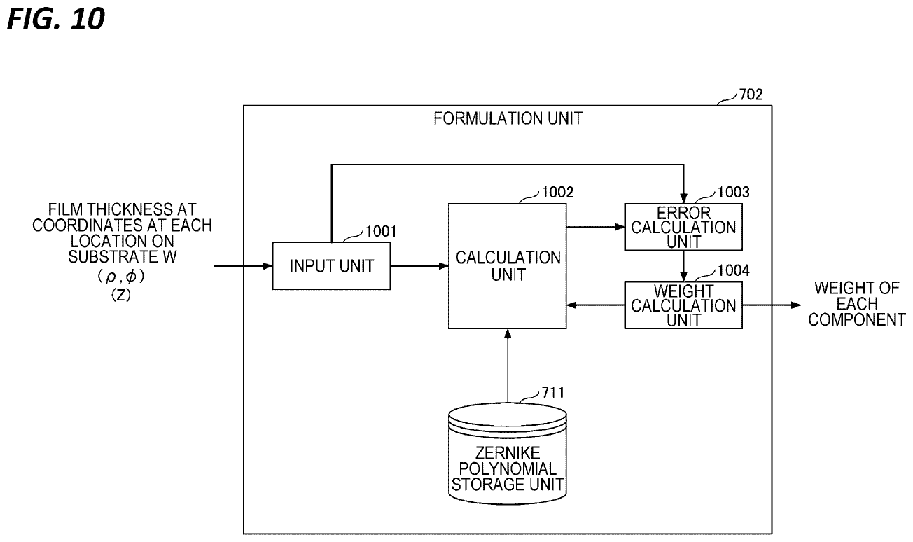

Next, a specific example of processing by the formulation unit 702 will be described. FIG. 10 is a view illustrating a specific example of processing by the formulation unit. As illustrated in FIG. 10, the formulation unit 702 further includes an input unit 1001, a calculation unit 1002, an error calculation unit 1003, and a weight calculation unit 1004.

The input unit 1001 acquires a film thickness measurement result notified by the film thickness measurement result acquisition unit 701. The film thickness measurement result notified by the film thickness measurement result acquisition unit 701 includes
coordinates (ρ, φ) indicating each in-plane location on the substrate W, and
a film thickness (Z) at coordinates.

The input unit 1001 inputs the coordinates indicating each in-plane location on the substrate W, which are included in the film thickness measurement result, into the calculation unit 1002. Also, the input unit 1001 notifies the error calculation unit 1003 of the film thickness at the coordinates included in the film thickness measurement result.

The calculation unit 1002 reads the Zernike polynomial from the Zernike polynomial storage 711, and inputs the coordinates indicating any one of in-plane locations on the substrate W, into each component of the Zernike polynomial. Also, the calculation unit 1002 multiplies the value of each component of the Zernike polynomial, which is calculated by inputting the coordinates indicating each in-plane location on the substrate W, by the weight (e.g., α₂ to α₁₁), and then performs a summation, and outputs the summation result to the error calculation unit 1003. The calculation unit 1002 calculates the summation result by using the weight (e.g., α₂ to α₁₁) of each component notified by the weight calculation unit 1004.

The calculation unit 1002 performs processing of outputting the summation results, on all coordinates indicating in-plane locations on the substrate W, and then outputs the summation results, on all coordinates included in the film thickness measurement result.

The error calculation unit 1003 compares the summation results at the coordinates output from the calculation unit 1002, to the film thicknesses at the coordinates notified by the input unit 1001, and calculates the sum of errors (e.g., least squares error) between the summation results at the coordinates and the film thicknesses. The error calculation unit 1003 notifies the weight calculation unit 1004 of the calculated sum of errors at the coordinates.

The weight calculation unit 1004 updates the weight (e.g., α₂ to an) of each component such that the sum of errors notified by the error calculation unit 1003 is minimized, and notifies the calculation unit 1002 of the updated weight. The calculation unit 1002, the error calculation unit 1003, and the weight calculation unit 1004 repeat the processing until the sum of errors is minimized. The weight calculation unit 1004 notifies the transfer position adjustment unit 703_1 and the process condition adjustment unit 703_2 of the weight (e.g., α₂ to α₁₁) of each component when the sum of errors is minimized.

### <Example of Weight of Each Component Before Adjustment Processing>

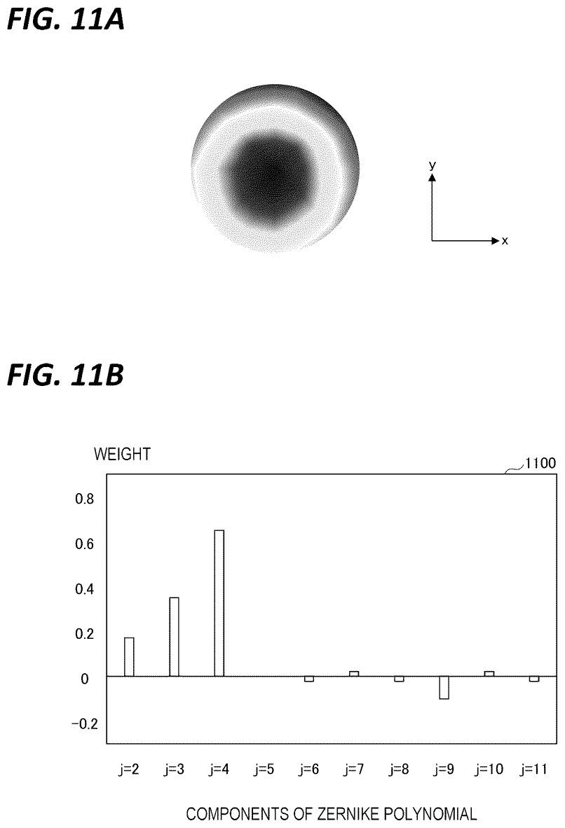

Next, descriptions will be made on a specific example of the weight of each component calculated by the formulation unit 702 before adjustment processing is performed. FIGS. 11A and 11B are views illustrating an example of the film thickness measurement result before adjustment processing, and the weight of each component in the Zernike polynomial.

Among these, FIG. 11A illustrates an example of the film thickness measurement result before processing of adjusting the transfer position of the substrate W and processing of adjusting a process condition are performed. The example of FIG. 11A illustrates that the center position of the concentric circles in the concentric film thickness distribution is shifted from the center position of the substrate W, and also film thicknesses vary depending on locations on the substrate W, and are non-uniform.

FIG. 11B illustrates the weight (e.g., α₂ to α₁₁) of each component calculated when the film thickness measurement result illustrated in FIG. 11A is formulated by using the Zernike polynomial. In a graph 1100 of FIG. 11B, the horizontal axis indicates each component (j=2 to 11) of the Zernike polynomial and the vertical axis indicates the weight (e.g., α₂ to α₁₁) of each component.

In the graph 1100, among components of the Zernike polynomial, the weights (α₂, α₃, and α₄) of the components j of 2, 3, and 4 are large.

The component j of 2 is a component corresponding to the combination of n=1 and m=1, and is the component related to the x-direction deviation amount among deviation amounts from the center position of the substrate W (see, e.g., the unit circle of n=1 and m=1 in FIG. 8B). The large weight of the component j of 2 indicates that the x-direction deviation amount is large.

The component j of 3 is a component corresponding to the combination of n=1 and m=−1, and is the component related to the y direction deviation amount among deviation amounts from the center position of the substrate W (see, e.g., the unit circle of n=1 and m=−1 in FIG. 8B). The large weight of the component j of 3 indicates that the y-direction deviation amount is large.

The component j of 4 is a component corresponding to the combination of n=2 and m=0, and is the component related to the process condition (see, e.g., the unit circle of n=2 and m=0 in FIG. 8B). The large weight of the component j of 4 indicates that film thicknesses vary concentrically from the center to the outside.

### <Specific Example of Processing by Transfer Position Adjustment Unit>

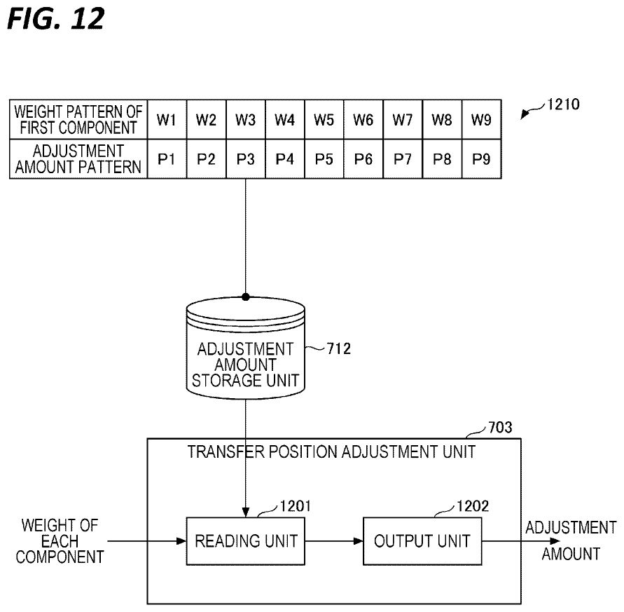

Next, a specific example of processing by the transfer position adjustment unit 703_1 will be described. Here, descriptions will be made on a specific example of processing in a case where the transfer position adjustment unit 703_1 directly calculates the adjustment amount for adjusting the transfer position of the substrate W by using the weight of the first component. FIG. 12 is a view illustrating a specific example of processing by the transfer position adjustment unit. As illustrated in FIG. 12, the transfer position adjustment unit 703_1 further includes a reading unit 1201 and an output unit 1202.

The reading unit 1201 acquires the weight of each component of the Zernike polynomial, from the formulation unit 702. The reading unit 1201 extracts the weights of the first component from the respective acquired weights of the components, and compares the weights to a weight pattern 1210 stored in the adjustment amount storage unit 712.

As illustrated in FIG. 12, the weight pattern 1210 includes information items of “weight pattern of first component” and “adjustment amount pattern.”

The “weight pattern of first component” stores various patterns related to a combination of weights of the first component. The example of the weight pattern 1210 illustrates that the nine patterns from “W1” to “W9” are included. In the nine patterns, the items included in the first component are the same, but the values included in the first component are different.

For example, when the items included in the first component are “the component j of 2” and “the component j of 3,” the weight pattern has different combinations of values.

That is,
“W1” has the weight of 0.2 for the component j of 2, and the weight of 0.3 for the component j of 3,
“W2” has the weight of 0.3 for the component j of 2, and the weight of 0.4 for the component j of 3,
“W3” has the weight of 0.4 for the component j of 2, and the weight of 0.5 for the component j of 3,
. . .
“W9” has the weight of 0.6 for the component j of 2, and the weight of 0.2 for the component j of 3.

The “adjustment amount pattern” stores “P1” to “P9” as adjustment amounts corresponding to “W1” to “W9” stored in the “weight pattern of first component.” “P1” to “P9” include various combinations of patterns having the x-direction adjustment amount and the y-direction adjustment amount of the transfer position of the substrate W.

The reading unit 1201 searches the weight pattern 1210 for a weight pattern similar to the extracted weight pattern of the first component, and then reads an adjustment amount pattern corresponding to the detected weight pattern so as to calculate the adjustment amount.

The output unit 1202 notifies the transfer device 120 of the adjustment amount calculated by the reading unit 1201 (the x-direction adjustment amount and the y-direction adjustment amount of the transfer position on the substrate W).

### <Specific Example of Processing by Process Condition Adjustment Unit>

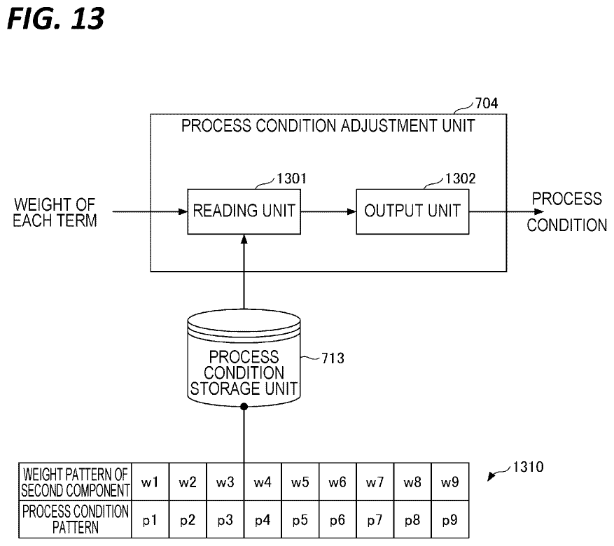

Next, a specific example of processing by the process condition adjustment unit 703_2 will be described. FIG. 13 is a view illustrating a specific example of processing by the process condition adjustment unit. As illustrated in FIG. 13, the process condition adjustment unit 703_2 further includes a reading unit 1301 and an output unit 1302.

The reading unit 1301 acquires the weight of each component of the Zernike polynomial, from the formulation unit 702. The reading unit 1301 extracts the weights of the second component from the respective acquired weights of the components, and compares the weights to a weight pattern 1310 stored in the process condition storage unit 713.

As illustrated in FIG. 13, the weight pattern 1310 includes information items of “weight pattern of second component” and “process condition pattern.”

The “weight pattern of second component” stores various patterns related to a combination of weights of the second component. The example of the weight pattern 1310 illustrates that the nine patterns from “w1” to “w9” are included. In the nine patterns, the items included in the second component are the same, but the values included in the second component are different.

For example, when the items included in the second component are “the component j of 4” and “the component j of 9,” the weight pattern has different combinations of values.

That is,
“w1” has the weight of 0.6 for the component j of 4, and the weight of −0.1 for the component j of 9,
“w2” has the weight of 0.5 for the component j of 4, and the weight of −0.2 for the component j of 9,
“w3” has the weight of 0.4 for the component j of 4, and the weight of −0.3 for the component j of 9,
“w9” has the weight of 0.7 for the component j of 4, and the weight of 1.0 for the component j of 9.

The “process condition pattern” stores “p1” to “p9” as process condition patterns corresponding to “w1” to “w9” stored in the “weight pattern of second component.” “p1” to “p9” include various combinations of patterns having process conditions (e.g., the target temperature, the type of processing gas, the gas flow rate, and the gas introduction time) for forming a film on the substrate W.

The reading unit 1301 searches the weight pattern 1310 for a weight pattern similar to the extracted weight pattern of the second component, and then reads a process condition pattern corresponding to the detected weight pattern so as to adjust the process condition.

The output unit 1302 notifies the film forming processing apparatus 110 of the process condition adjusted by the reading unit 1301.

### <Flow of Adjustment Processing>

Next, the flow of adjustment processing by the film forming processing system 100 will be described. Prior to description, first, the flow of adjustment processing performed by the film forming processing system of a comparative example will be described so as to clarify the differences from the adjustment processing performed by the film forming processing system of the comparative example. The film forming processing system of the comparative example refers to a system in which as for the adjustment processing for realizing a film thickness distribution that satisfies predetermined requirements, the processing of adjusting the transfer position of the substrate W and the processing of adjusting the process condition are separately performed as two stages.

### (1) Flow of Adjustment Processing by Film Forming Processing System of Comparative Example

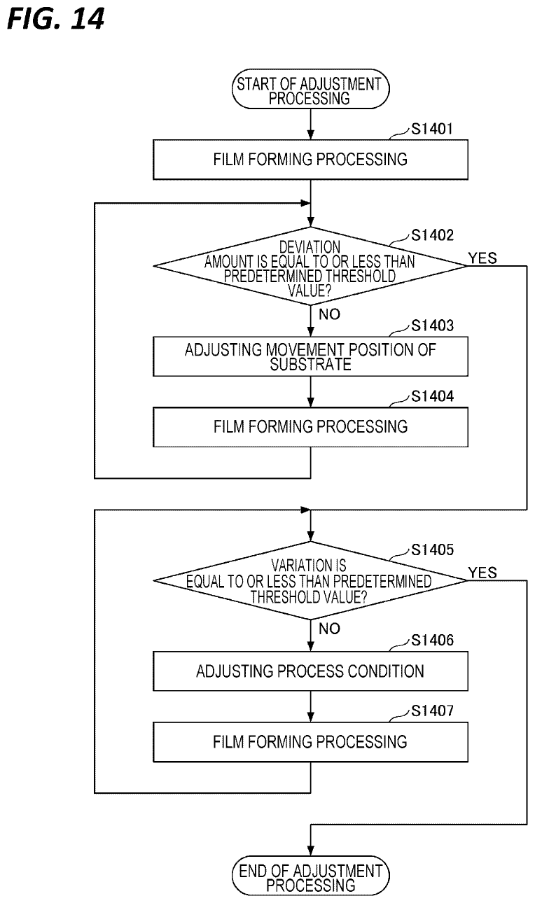

FIG. 14 is a flow chart illustrating the flow of adjustment processing by the film forming processing system of the comparative example.

In step S1401, in the film forming processing system of the comparative example, the film forming processing apparatus forms a film on a substrate W.

In step S1402, in the film forming processing system of the comparative example, the film thickness measuring device measures a film thickness at each location on the substrate W on which a film has been formed. Also, the adjustment processing apparatus determines whether a deviation amount between the center position of the concentric film thickness distribution and the center position of the substrate W is equal to or less than a predetermined threshold value based on the film thickness measured by the film thickness measuring device, at each location on the substrate W. In step S1402, when it is determined that the deviation amount is greater than the predetermined threshold value (NO in step S1402), the process proceeds to step S1403.

In step S1403, in the film forming processing system of the comparative example, the adjustment processing apparatus calculates the adjustment amount of the transfer position of the substrate W, and the transfer device adjusts the transfer position of the substrate W according to the calculated adjustment amount.

In step S1404, in the film forming processing system of the comparative example, the film forming processing apparatus forms a film on the substrate W and the process returns to step S1402.

In the film forming processing system of the comparative example, until the adjustment processing apparatus determines that the deviation amount is equal to or less than the predetermined threshold value in step S1402, the process from step S1402 to step S1404 is repeated.

Meanwhile, in step S1402, when it is determined that the deviation amount between the center position of the concentric film thickness distribution and the center position of the substrate W is equal to or less than the predetermined threshold value (YES in step S1402), the process proceeds to step S1405.

In step S1405, in the film forming processing system of the comparative example, the adjustment processing apparatus determines whether a variation in film thicknesses measured by the film thickness measuring device, at locations on the substrate W, is equal to or less than a predetermined threshold value. In step S1405, when it is determined that the variation is greater than the predetermined threshold value (NO in step S1405), the process proceeds to step S1406.

In step S1406, in the film forming processing system of the comparative example, the adjustment processing apparatus adjusts a process condition, and notifies the film forming processing apparatus of the adjusted process condition.

In step S1407, in the film forming processing system of the comparative example, the film forming processing apparatus forms a film on the substrate W based on the adjusted process condition, and the process returns to step S1405.

In the film forming processing system of the comparative example, until the adjustment processing apparatus determines that the variation is equal to or less than the predetermined threshold value in step S1405, the process from step S1405 to S1407 is repeated.

Meanwhile, in step S1405, when it is determined that the variation is equal to or less than the predetermined threshold value (YES in step S1405), the adjustment processing is ended.

### (2) the Flow Chart of Adjustment Processing by the Film Forming Processing System 100

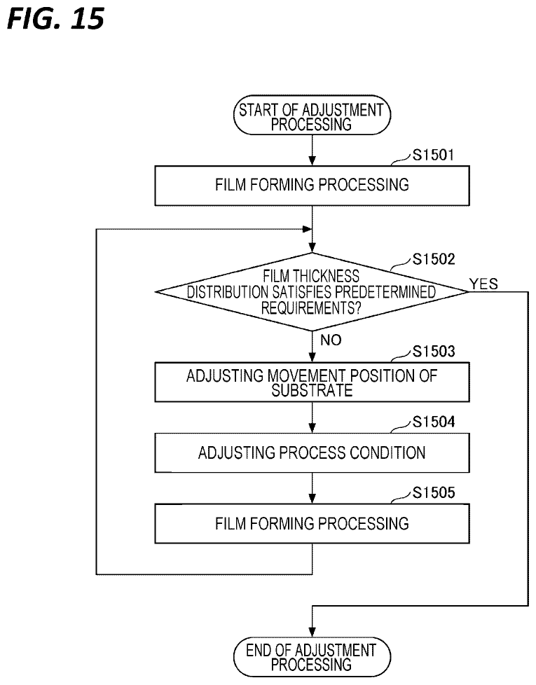

FIG. 15 is a flow chart illustrating the flow of adjustment processing by the film forming processing system.

In step S1501, in the film forming processing system 100, the film forming processing apparatus 110 forms a film on the substrate W.

In step S1502, in the film forming processing system 100, the film thickness measuring device 130 measures a film thickness at each location on the substrate W on which a film has been formed. Also, the adjustment processing apparatus 140 determines whether a film thickness distribution of the substrate W measured by the film thickness measuring device 130 satisfies predetermined requirements. Specifically, the adjustment processing apparatus 140 determines
whether a deviation amount between the center position of the concentric film thickness distribution, and the center position of the substrate W is equal to or less than a predetermined threshold value, and
whether a variation in film thicknesses at locations on the substrate W is equal to or less than a predetermined threshold value.

In step S1502, when it is determined that the film thickness distribution does not satisfy predetermined requirements (NO in step S1502), the process proceeds to step S1503.

In step S1503, in the film forming processing system 100, the adjustment processing apparatus 140 formulates the film thickness measurement result measured by the film thickness measuring device 130, so as to calculate the weight of each component of the Zernike polynomial. Also, the adjustment processing apparatus 140 calculates the adjustment amount of the transfer position based on the weight of the first component, and the transfer device 120 adjusts the transfer position of the substrate W according to the calculated adjustment amount.

In step S1504, in the film forming processing system 100, the adjustment processing apparatus 140 adjusts a process condition based on the weight of the second component, and notifies the film forming processing apparatus 110 of the adjusted process condition.

In step S1505, in the film forming processing system 100, the film forming processing apparatus 110 forms a film on the substrate W transferred to the adjusted transfer position, based on the adjusted process condition, and the process returns to step S1502.

In the film forming processing system 100, until the adjustment processing apparatus 140 determines that predetermined requirements are satisfied in step S1502, the process from step S1502 to S1505 is repeated.

Meanwhile, in step S1502, when it is determined that the film thickness distribution satisfies predetermined requirements (YES in step S1502), the adjustment processing is ended.

In this manner, in the film forming processing system 100, by using the film thickness measurement result acquired by one film formation, an index value including both information required for a work for adjusting the transfer position of the substrate, and information required for a work for adjusting a process condition is calculated. As a result, in the film forming processing system 100, unlike in the film forming processing system of the comparative example, the adjustment operations do not need to be separately performed as two stages. As a result, in the film forming processing system 100, it is possible to shorten the time for the adjustment operations in the film forming process.

### <Example of Weight of Each Component After Adjustment Processing>

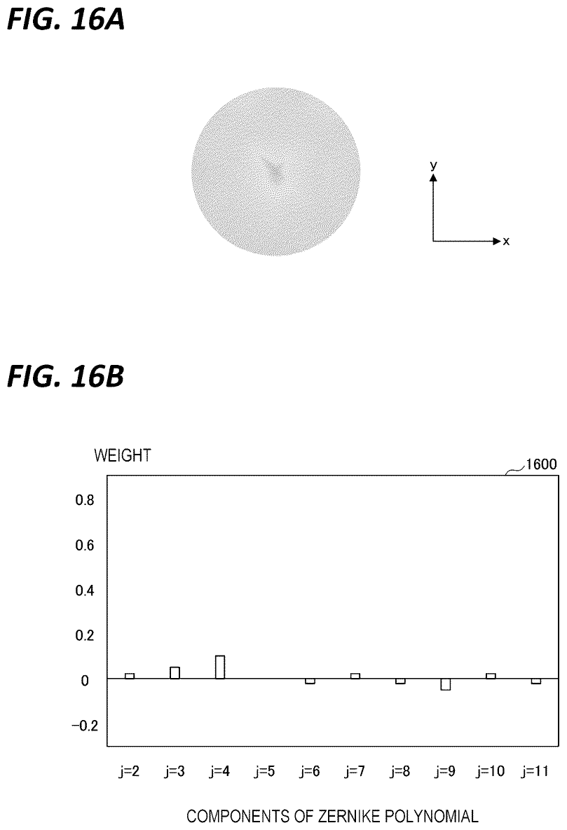

Next, descriptions will be made on a specific example of the weight of each component calculated by the formulation unit 702 after adjustment processing is performed. FIGS. 16A and 16B are views illustrating an example of the film thickness measurement result after adjustment processing, and the weight of each component in the Zernike polynomial.

Among these, FIG. 16A illustrates an example of the film thickness measurement result after processing of adjusting the transfer position of the substrate W and processing of adjusting a process condition are executed. The example of FIG. 16A illustrates that the center position of the film thickness distribution coincides with the center position of the substrate W, and film thicknesses do not vary depending on locations on the substrate W and are uniform.

FIG. 16B illustrates the weight of each component calculated when the film thickness measurement result illustrated in FIG. 16A is formulated by using the Zernike polynomial. In a graph 1600 of FIG. 16B, the horizontal axis indicates each component of the Zernike polynomial and the vertical axis indicates the weight of each component.

In the graph 1600, all of the weights of components in the Zernike polynomial are small. For example, the component j of 2 after adjustment processing is small compared to the component j of 2 before adjustment processing (FIG. 11B). Therefore, it can be quantitatively grasped that after adjustment processing, among deviation amounts of the center position of the film thickness distribution from the center position of the substrate W, the x-direction deviation amount is small.

Also, the component j of 3 after adjustment processing is small compared to the component j of 3 before adjustment processing (FIG. 11B). Therefore, it can be quantitatively grasped that after adjustment processing, among deviation amounts of the center position of the film thickness distribution from the center position of the substrate W, the y-direction deviation amount is small.

Also, the component j of 4 after adjustment processing is small compared to the component j of 4 before adjustment processing (FIG. 11B). Therefore, it can be quantitatively grasped that before adjustment processing, film thicknesses vary concentrically from the center to the outside whereas after adjustment processing, such a variation of film thicknesses is greatly improved.

### SUMMARY

As can be seen from the above description, the adjustment processing apparatus 140 according to the first embodiment
acquires the film thickness measurement result of the substrate W including a film formed thereon by the film forming processing apparatus 110,
formulates the film thickness measurement result using the Zernike polynomial, and
adjusts the transfer position of the substrate W and the process condition of the film forming processing apparatus 110, based on the weight of each component of the Zernike polynomial calculated during formulation.

In this manner, in the film forming process, the adjustment processing apparatus 140 according to the first embodiment calculates an index value including both information required for a work for adjusting the transfer position of the substrate, and information required for a work for adjusting a process condition by using the film thickness measurement result acquired by one film formation. Accordingly, by the adjustment processing apparatus 140 according to the first embodiment, the adjustment operations do not need to be separately performed as two stages. As a result, it is possible to shorten the time for the adjustment operations in the film forming process by the adjustment processing apparatus 140.

### Second Embodiment

In the description on the first embodiment, the weight of each component of the Zernike polynomial is used to adjust the transfer position of the substrate W, and to adjust the process condition of the film forming processing apparatus 110. However, the weight of each component of the Zernike polynomial may be output as an evaluation index of the film thickness distribution of the substrate W on which a film has been formed.

For example, the weight of the first component may be output as an evaluation index indicating the deviation amount of the center position of the concentric circles in the concentric film thickness distribution, from the center position of the substrate W. Also, the weight of the second component may be output as an evaluation index indicating the variation in the film thicknesses at locations on the substrate W.

In this manner, by outputting the weight of each component as an evaluation index, for example, it is possible to objectively grasp the effect of adjustment processing from the difference between the value of the evaluation index before adjustment processing, and the value of the evaluation index after adjustment processing.

Also, in a case where the weight of each component is used as the evaluation index, for example, when determining whether the film thickness distribution satisfies predetermined requirements during adjustment processing (in step S1502 of FIG. 15), it is possible to determine
whether the weight pattern of the first component satisfies a predetermined condition, and
whether the weight pattern of the second component satisfies a predetermined condition.

Also, in the configuration of the first embodiment, the weight pattern 1210 indicating the correspondence between the weight pattern of the first component and the adjustment amount pattern is stored in the adjustment amount storage unit 712. However, the correspondence between the weight pattern of the first component and the adjustment amount pattern may be learned by a learning model. Accordingly, it is possible to derive the adjustment amount pattern from the weight pattern of the first component by using the trained model, so that the adjustment amount may be calculated.

Similarly, in the configuration of the first embodiment, the weight pattern 1310 indicating the correspondence between the weight pattern of the second component and the process condition is stored in the process condition storage unit 713. However, the correspondence between the weight pattern of the second component and the process condition may be learned by a learning model. Accordingly, it is possible to derive the process condition from the weight pattern of the second component by using the trained model, so that the process condition may be adjusted.

### Third Embodiment

In the description on each of the embodiments, the process condition adjustment unit 703_2 adjusts a process condition so as to eliminate the variation in the film thicknesses at locations and make the film thicknesses uniform. However, the function of the process condition adjustment unit 703_2 is not limited to this. For example, the process condition adjustment unit 703_2 may adjust a process condition such that an average value of film thicknesses at locations reaches a target value. Specifically, a configuration may be made in which the “process condition pattern” of the weight pattern 1310 stores a process condition that allow the average value of film thicknesses at locations to reach a target value.

Alternatively, the process condition adjustment unit 703_2 may adjust a process condition so as to eliminate the variation in the film thicknesses at locations and make the film thicknesses uniform, and to allow the average value of the film thicknesses at locations to reach a target value. Specifically, a configuration may be made in which the “process condition pattern” of the weight pattern 1310 stores a process condition that eliminates the variation in the film thicknesses at locations and make the film thicknesses uniform, and allow the average value of the film thicknesses at locations to reach a target value.

That is, determining whether the film thickness distribution satisfies a predetermined condition includes
determining whether a deviation amount between the center position of the concentric film thickness distribution and the center position of the substrate W is equal to or less than a predetermined threshold value, and
either or both of determining whether a variation in film thicknesses at locations on the substrate W is equal to or less than a predetermined threshold value, and determining whether an error between the average value of film thicknesses at locations of the substrate W and the target value is equal to or less than a predetermined threshold value.

Therefore, a film thickness distribution satisfying predetermined requirements indicates either or both of the followings:
a deviation amount between the center position of the concentric film thickness distribution and the center position of the substrate W is equal to or less than a predetermined threshold value, and
a variation in film thicknesses at locations on the substrate W is equal to or less than a predetermined threshold value, and an error between the average value of film thicknesses at locations of the substrate W and the target value is equal to or less than a predetermined threshold value.

### Fourth Embodiment

In the description on each of the embodiments, a Zernike polynomial is used as an orthogonal polynomial, but orthogonal polynomial other than the Zernike polynomial may be used.

Also, in each of the embodiments, the Fringe notation method for the Zernike polynomial is used for formulation, but notation methods other than the Fringe notation method may be used for formulation. Which notation method to use may be determined based on, for example, the type of the film forming processing apparatus. Since the order of components changes according to the difference between notation methods, for example, a notation method may be selected such that among values of positions within unit circles of components illustrated in FIG. 8B, a component having a value close to a film thickness distribution having a high occurrence frequency appears early.

Any type of film forming processing apparatus may be employed. For example, the film forming processing apparatus includes film forming processing apparatuses in which a film is formed by any film forming method (a chemical vapor deposition method, a sputtering method, or an atomic layer deposition method). Also, the film forming processing apparatus includes film forming processing apparatuses in which a film is formed by any processing method (a single wafer type or a batch type).

Also, in each of the embodiments, the film forming processing apparatus 110 and the adjustment processing apparatus 140 are configured as separate apparatuses, but the film forming processing apparatus 110 and the adjustment processing apparatus 140 may be configured as an integrated apparatus. Alternatively, a part of functions of the adjustment processing apparatus 140 may be realized in the film forming processing apparatus 110.

Also, in the description on each of the embodiments, the adjustment processing apparatus 140 is realized by a piece of hardware, but the adjustment processing apparatus 140 may be realized by a plurality of hardware components. For example, some or all of the functions of the adjustment processing apparatus 140 may be realized in any apparatus within the film forming processing system 100.

According to the present disclosure, it is possible to shorten the time for the adjustment operation in the film forming process.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. An adjustment processing apparatus comprising:
film thickness measurement result acquisition circuitry configured to acquire a film thickness measurement result of a substrate including a film formed thereon by a film forming processing apparatus;
formulation circuitry configured to formulate the film thickness measurement result using an orthogonal polynomial; and
adjustment circuitry configured to adjust a transfer position of the substrate and a process condition of the film forming processing apparatus based on a weight of each component of the orthogonal polynomial calculated during formulation.

2. The adjustment processing apparatus according to claim 1, wherein the adjustment circuitry include:
transfer position adjustment circuitry configured to adjust the transfer position of the substrate based on a weight of a first component of the orthogonal polynomial calculated through the formulation; and
process condition adjustment circuitry configured to adjust the process condition of the film forming processing apparatus based on a weight of a second component of the orthogonal polynomial calculated through the formulation.

3. The adjustment processing apparatus according to claim 2, wherein the weight of each component calculated when the film thickness measurement result is formulated using the orthogonal polynomial is output as an evaluation index of the film thickness measurement result.

4. The adjustment processing apparatus according to claim 3, wherein the weight of the first component calculated when the film thickness measurement result is formulated using the orthogonal polynomial is output as an evaluation index indicating a deviation amount between a center position of a film thickness distribution and a center position of the substrate.

5. The adjustment processing apparatus according to claim 3, wherein the weight of the second component calculated when the film thickness measurement result is formulated using the orthogonal polynomial is output as an evaluation index indicating a variation in film thicknesses at locations on the substrate.

6. The adjustment processing apparatus according to claim 3, wherein the orthogonal polynomial is a Zernike polynomial.

7. The adjustment processing apparatus according to claim 2, wherein the transfer position adjustment circuitry refer to a storage in which a weight pattern of the first component is associated with an adjustment amount pattern of the transfer position of the substrate, and search for a weight pattern similar to the weight pattern of the first component calculated when the film thickness measurement result is formulated using the orthogonal polynomial, thereby calculating an adjustment amount of the transfer position of the substrate.

8. The adjustment processing apparatus according to claim 2, wherein the process condition adjustment circuitry refer to a storage in which a weight pattern of the second component is associated with a process condition pattern of the film forming processing apparatus, and search for a weight pattern similar to the weight pattern of the second component calculated when the film thickness measurement result is formulated using the orthogonal polynomial, thereby adjusting the process condition.

9. The adjustment processing apparatus according to claim 2, wherein the transfer position adjustment circuitry calculate an adjustment amount of the transfer position of the substrate using a trained model in which a correspondence between a weight pattern of the first component and an adjustment amount pattern of the transfer position of the substrate is learned.

10. The adjustment processing apparatus according to claim 2, wherein the process condition adjustment circuitry adjust the process condition using a trained model in which a correspondence between a weight pattern of the second component and a process condition pattern of the film forming processing apparatus is learned.

11. The adjustment processing apparatus according to claim 1, wherein the adjustment circuitry determine whether a film thickness distribution satisfies a predetermined condition, and, when determined that the film thickness distribution does not satisfy predetermined requirements, adjust the transfer position of the substrate and the process condition of the film forming processing apparatus.

12. The adjustment processing apparatus according to claim 11, wherein the determining whether the film thickness distribution satisfies the predetermined condition includes:
determining whether a deviation amount between a center position of the film thickness distribution and a center position of the substrate is equal to or less than a predetermined threshold value, and
either or both of determining whether a variation in film thicknesses at locations on the substrate is equal to or less than a predetermined threshold value, and determining whether an error between an average value of the film thicknesses at locations on the substrate and a target value is equal to or less than a predetermined threshold value.

13. The adjustment processing apparatus according to claim 11, wherein determining whether the film thickness distribution satisfies the predetermined condition includes:
determining whether a weight pattern of each component of the orthogonal polynomial satisfies the predetermined requirements.

14. A film forming processing system comprising:
the film forming processing apparatus according to claim 1;
a transfer device;
a film thickness measuring device; and
an adjustment processing apparatus.

15. An adjustment processing method in which a computer executes a series of process including:
acquiring a film thickness measurement result of a substrate including a film formed thereon by a film forming processing apparatus;
formulating the film thickness measurement result using an orthogonal polynomial; and
adjusting a transfer position of the substrate and a process condition of the film forming processing apparatus based on a weight of each component of the orthogonal polynomial calculated during formulation.

16. A non-transitory computer-reading storage medium having stored therein an adjustment processing program that causes a computer to execute an adjustment processing method including:
acquiring a film thickness measurement result of a substrate including a film formed thereon by a film forming processing apparatus;
formulating the film thickness measurement result using orthogonal polynomial; and
adjusting a transfer position of the substrate and a process condition of the film forming processing apparatus based on a weight of each component of the orthogonal polynomial calculated during formulation.
